(19) United States
(12) Patent Application Publication
(10) Pub. No.: US 2023/0343656 A1
(43) Pub. Date: Oct. 26, 2023

(54) SEMICONDUCTOR STRUCTURE AND METHOD FOR FABRICATING SAME

(71) Applicant: Changxin Memory Technologies, Inc., Hefei (CN)

(72) Inventor: Qilong WU, HEFEI (CN)

(21) Appl. No.: 18/197,240

(22) Filed: May 15, 2023

Related U.S. Application Data
(63) Continuation of application No. PCT/CN2022/124201, filed on Oct. 9, 2022.

(30) Foreign Application Priority Data
Apr. 25, 2022 (CN) 202210464674.1

(51) Int. Cl. H01L 21/66; H01L 23/00; H01L 23/544

(52) U.S. Cl. CPC H01L 22/32; H01L 24/06; H01L 23/544; H01L 24/03; H01L 2224/06515; H01L 2224/06151; H01L 2223/54433; H01L 2224/03

(57) ABSTRACT

A semiconductor structure includes a base and a re-distribution layer. The re-distribution layer is disposed on the base and includes a bond pad and a probe pad, the bond pad and the probe pad are disposed adjacent to each other, and a recess is formed in the re-distribution layer and is disposed between the bond pad and the probe pad.

### CROSS-REFERENCE TO RELATED APPLICATIONS

This application is a continuation application of International Patent Application No. PCT/CN2022/124201, filed on Oct. 9, 2022, which claims priority to Chinese Patent Application No. 202210464674.1, filed on Apr. 25, 2022 and entitled “SEMICONDUCTOR STRUCTURE AND METHOD FOR FABRICATING SAME”. The above-referenced applications are incorporated herein by reference in their entirety.

### TECHNICAL FIELD

The present Invention relates to the field of semiconductor technologies, and in particular, to a semiconductor structure and a method for fabricating a semiconductor structure.

### BACKGROUND

A re-distribution layer (RDL) is used when a contact point (I/O pad) of an originally designed integrated circuit (IC) is relocated using a wafer level metal wiring and a welding pad so that the IC can be used in different packaging configurations.

The re-distribution layer may include a probe pad and a bond pad. When there is no optical identification layer between the probe pad and the bond pad, the test device may not be able to identify the probe pad during automatic testing, causing an error.

### SUMMARY

The present invention provides a semiconductor structure and a method for fabricating a semiconductor structure, so as to improve test performance of the semiconductor structure.

According to a first aspect of the present invention, a semiconductor structure is provided, including: a base; and a re-distribution layer, where the re-distribution layer is disposed on the base and includes a bond pad and a probe pad, the bond pad and the probe pad are disposed adjacent to each other, and at least one recess is formed in the re-distribution layer and is disposed between the bond pad and the probe pad.

In some embodiments of the present invention, is the at least one recess consists of one recess, and the bond pad and the probe pad are respectively disposed on two opposite sides of the recess.

In some embodiments of the present invention, widths of the recess sampled along a length direction of the recess are uniform.

In some embodiments of the present invention, widths of the recess sampled along a length direction of the recess are varied.

In some embodiments of the present invention, the widths of the recess gradually decreases from two opposite edge regions of the recess to a middle region of the recess.

In some embodiments of the present invention, the at least one recess consists of a plurality of the recesses, and the bond pad and the probe pad are respectively disposed on two opposite sides of a recess region formed by the plurality of the recesses.

In some embodiments of the present invention, the recesses are disposed and spaced apart along a width direction of the recess region.

In some embodiments of the present invention, the recesses are disposed and spaced apart along a length direction of the recess region, where the length direction of the recess region is substantially parallel to an edge line between the probe pad and the recesses.

In some embodiments of the present invention, the plurality of the recesses are arranged in at least two rows in the recess region.

In some embodiments of the present invention, the base includes: a substrate; a conductive layer, where the conductive layer is disposed on the substrate, and the re-distribution layer is connected to the conductive layer; and a dielectric layer, where the dielectric layer is disposed on the substrate and includes a first opening, and a first orthographic projection of the recess on the substrate is within a second orthographic projection of the first opening on the substrate.

In some embodiments of the present invention, the re-distribution layer fills a portion of the first opening.

In some embodiments of the present invention, an air gap is formed on a side of the re-distribution layer facing toward the first opening.

In some embodiments of the present invention, the first opening exposes the conductive layer.

In some embodiments of the present invention, a width of the first opening is not greater than 3 μm.

In some embodiments of the present invention, a width of the first opening is 1 μm to 3 μm.

In some embodiments of the present invention, the semiconductor structure further includes: an optical identification layer, where the optical identification layer is disposed on the re-distribution layer, and the optical identification layer includes a second opening to expose the bond pad, the probe pad, and the recess.

According to a second aspect of the present invention, a method for fabricating a semiconductor structure is provided, including: providing a base; forming a first opening in the base; and forming a re-distribution layer on the base such that a recess is formed between a bond pad and a probe pad of the re-distribution layer, where a first orthographic projection of the recess on the base is within a second orthographic projection of the first opening on the base.

In some embodiments of the present invention, a plurality of first openings are formed in the base, so that a plurality of recesses are formed in the re-distribution layer.

In some embodiments of the present invention, the base includes a substrate and a conductive layer and a dielectric layer that are sequentially formed on the substrate, the first opening is formed in the dielectric layer, and the re-distribution layer is formed on the dielectric layer.

In some embodiments of the present invention, the method for fabricating a semiconductor structure further includes: forming an optical identification layer on the re-distribution layer; and forming a second opening in the optical identification layer to expose the bond pad, the probe pad, and the recess.

### BRIEF DESCRIPTION OF DRAWINGS

Objectives, features, and advantages of the present invention become clearer from the following detailed description of example embodiments of the present invention when considered with reference to the accompanying drawings. The drawings are merely example illustrations of the present invention and are not necessarily drawn to scale. In the drawings, a same reference numeral indicates same or similar parts.

FIG. 1 is a flowchart of a method for fabricating a semiconductor structure according to some embodiments;

FIG. 2 is a schematic cross-sectional view of a semiconductor structure according to some embodiments;

FIG. 3 is a schematic structural diagram of a semiconductor structure according to a first example embodiment;

FIG. 4 is a schematic structural diagram of a semiconductor structure according to a second example embodiment;

FIG. 5 is a schematic structural diagram of a semiconductor structure according to a third example embodiment;

FIG. 6 is a schematic structural diagram of a semiconductor structure according to a fourth example embodiment;

FIG. 7 is a schematic structural diagram of a semiconductor structure according to a fifth example embodiment; and

FIG. 8 is a schematic structural diagram of a semiconductor structure according to a sixth example embodiment.

Description of reference numerals: 10: base; 11: substrate; 12: conductive layer; 13: dielectric layer; 131: first opening; 20: re-distribution layer; 21: bond pad; 22: probe pad; 23: recess; 231: edge region; 232: middle region; 24: air gap; 30: optical identification layer; 31: second opening.

### DESCRIPTION OF EMBODIMENTS

Some typical embodiments that embody the features and advantages of the present invention are detailed in the following description. It should be understood that the present invention can have various variations in different embodiments without departing from the scope of the present invention, and that the description and drawings therein are illustrative in nature and are not intended to limit the present invention.

In the following description of some different example embodiments of the present invention, reference is made to the accompanying drawings, which form a part of the present invention. The drawings illustrate different example structures, systems, and steps that can implement some aspects of the present invention. It should be understood that other specific solutions for the components, structures, example apparatuses, systems, and steps may be used, and structural and functional modifications can be made without departing from the scope of the present invention. In addition, although terms “above”, “between”, “within”, and the like may be used in this specification to describe different example features and elements of the present invention, these terms are used herein for convenience purposes only, for example, based on the example direction shown in the accompanying drawings. Nothing in this specification should be construed as requiring a particular three-dimensional orientation of a structure to fall within the scope of the present invention.

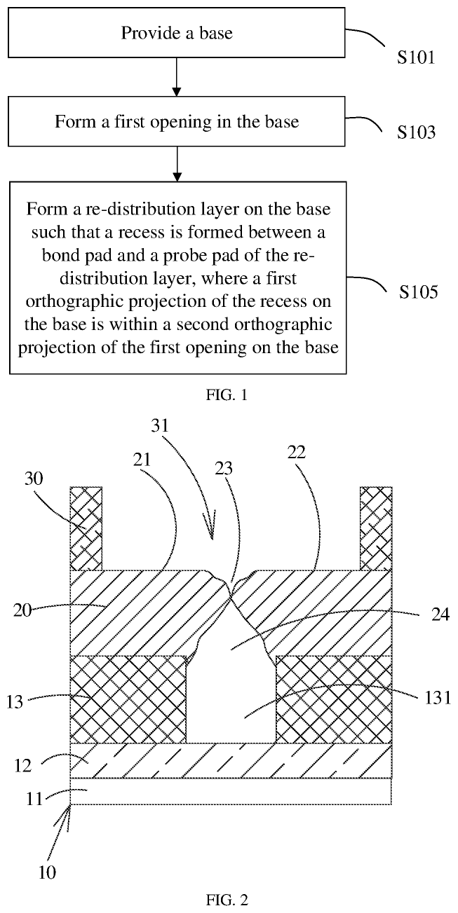

At least one embodiment of the present invention provides a method for fabricating a semiconductor structure. Referring to FIG. 1 to FIG. 8, the method for fabricating a semiconductor structure includes:

S101: Provide a base 10.

S103: Form a first opening 131 in the base 10.

S105: Form a re-distribution layer 20 on the base 10 such that a recess 23 is formed between a bond pad 21 and a probe pad 22 of the re-distribution layer 20, where a first orthographic projection of the recess 23 on the base 10 is within a second orthographic projection of the first opening 131 on the base 10.

According to the method for fabricating a semiconductor structure in some embodiments of the present invention, the first opening 131 is formed in the base 10, and therefore in the process of forming the re-distribution layer 20 on the base 10, the recess 23 can be formed between the bond pad 21 and the probe pad 22 of the re-distribution layer 20 such that the recess 23 can be used as an optical identification pattern on a side of the probe pad 22. The techniques avoids a problem that because there is no optical identification pattern between the bond pad 21 and the probe pad 22, a test device cannot identify the probe pad 22 during automatic testing, causing an error. As such, test performance of the semiconductor structure is improved.

It should be noted that the first opening 131 is formed in the base 10, and therefore in the process of depositing a metal material on the base 10 to form the re-distribution layer 20, a portion of the metal material may sinks into the first opening 131 such that a recess 23 is formed on an upper surface of the re-distribution layer 20, and the recess 23 can be used as an optical identification pattern on a side of the probe pad 22. In an example in which a material of the re-distribution layer 20 includes aluminum (Al), because a width of the first opening 131 is small, when depositing A1 to form the re-distribution layer 20, A1 is not deposited at a bottom and a bottom edge of the first opening 131. The Al layer forms an overhang over the first opening, thereby forming the recess 23 and an air gap 24 below the recess, as shown in FIG. 2.

In some embodiments, the width of the first opening 131 is not greater than 3 μm. To ensure that the recess 23 can be formed in the re-distribution layer 20, a large quantity of metal materials may not be deposited into the first opening 131, since depositing a large quantity of metal materials may result in forming a large-size recess 23 in the re-distribution layer 20, affecting the structural performance of the re-distribution layer 20.

In some embodiments, the width of the first opening 131 is 1 μm to 3 μm, which not only can ensure that the recess 23 can be formed in the re-distribution layer 20, but also can avoid an excessively small size of the recess 23 such that the recess 23 can be reliably used as the optical identification pattern of the probe pad 22.

In some embodiments, the width of the first opening 131 may be 1 μm, 1.1 μm, 1.2 μm, 1.3 μm, 1.5 μm, 1.6 μm, 1.8 μm, 2 μm, 2.1 μm, 2.2 μm, 2.3 μm, 2.5 μm, 2.6 μm, 2.7 μm, 2.8 μm, 2.9 μm, or 3 μm.

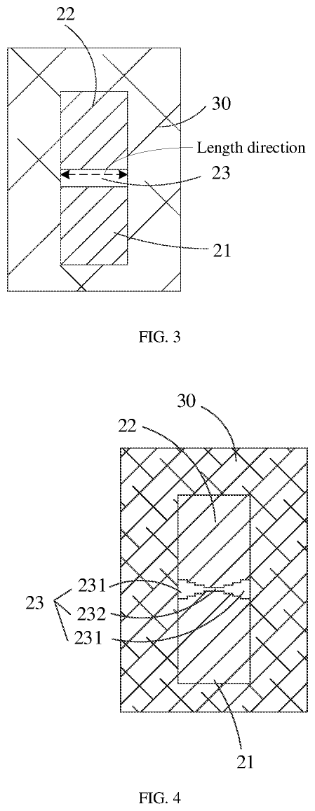

In some embodiments, a first opening 131 is formed in the base 10 such that a recess 23 is formed in the re-distribution layer 20. As shown in FIG. 3 and FIG. 4, the bond pad 21 and the probe pad 22 are respectively disposed on two opposite sides of the recess 23 such that the recess 23 can be used as an optical identification pattern for the probe pad 22, such that the probe pad 22 can be used for electrical performance testing on the semiconductor structure.

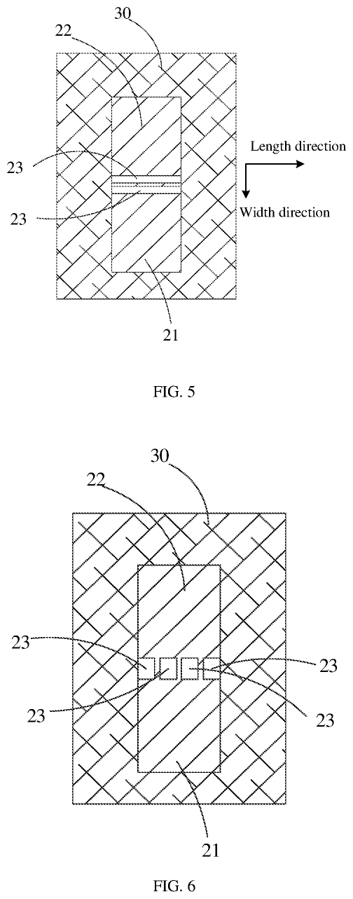

In some embodiments, a plurality of first openings 131 are formed in the base 10 such that a plurality of recesses 23 are formed in the re-distribution layer 20. As shown in FIG. 5 to FIG. 7, the bond pad 21 and the probe pad 22 are respectively disposed on two opposite sides of a recess region formed by the plurality of recesses 23 such that the plurality of recesses 23 can jointly be used as an optical identification pattern for the probe pad 22, such that the probe pad 22 can be used for electrical performance testing on the semiconductor structure.

It should be noted that a quantity and a specific structural form of the recesses 23 may not be limited, provided that i the recess or recesses 23 can be used as an optical identification pattern of the probe pad 22. A structural form of the first opening 131 may be consistent with that of the recess 23. For example, when there may be one first opening 131, one recess 23 can be formed in the re-distribution layer 20. In some embodiments, when there may be a plurality of first openings 131, a plurality of recesses 23 can be correspondingly formed in the re-distribution layer 20. Widths of the first openings 131 sampled along a length direction of the first openings 131 may be uniform. The widths of the first openings 131 sampled along a length direction of the first openings 131 may be varied.

In some embodiments, when one first opening 131 is present, the widths of the first opening 131 may be uniform such that the widths of the formed recess 23 sampled along a length direction of the recess may be uniform, as shown in FIG. 3.

In some embodiments, when one first opening 131 is present, and at least a portion of the widths of the first opening 131 is varied such that at least a portion of the widths of the formed recess 23 sampled along a length direction of the recess may be varied, as shown in FIG. 4.

In some embodiments, when a plurality of first openings 131 are present, for example, there may be two first openings 131, the two first openings 131 may be spaced apart such that the two recesses 23 correspondingly formed may be spaced apart, as shown in FIG. 5.

In some embodiments, when a plurality of first openings 131 are present, the plurality of first openings 131 may be spaced apart in a first direction (e.g., a length direction of the opening region formed by the plurality of first openings 131), where the first direction is substantially parallel to an edge line of the probe pad 22 in boundary with the recess region formed by the plurality of the recesses such that the plurality of recesses 23 formed may be spaced apart in the first direction, as shown in FIG. 6.

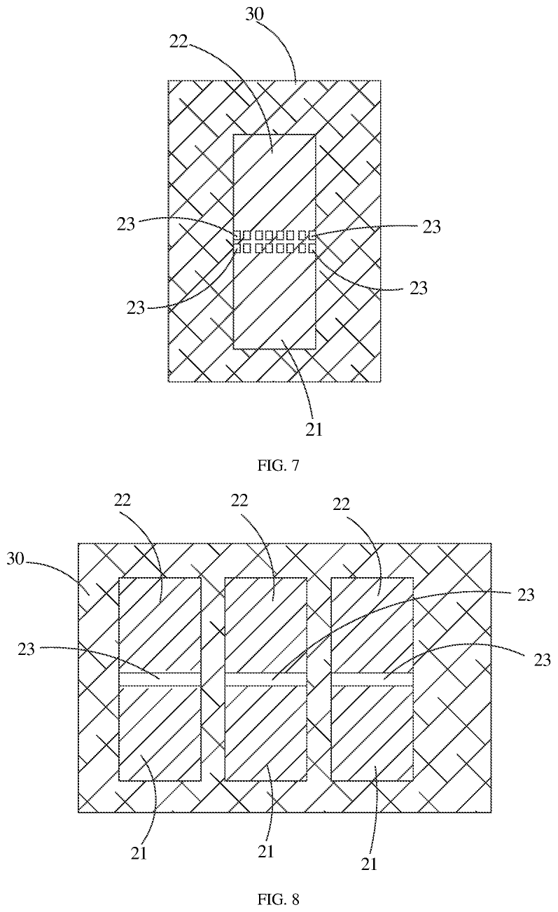

In some embodiments, there may be a plurality of first openings 131, and the plurality of first openings 131 may be arranged in at least two rows in a second direction (e.g., a width direction of the opening region formed by the plurality of first openings 131) perpendicular to the first direction such that at least two rows of recesses 23 can be formed. For example, the first openings 131 may be arranged in two rows such that two rows of recesses 23 are formed, as shown in FIG. 7. In some embodiments, an air gap 24 is formed on a side of the re-distribution layer 20 facing toward the first opening 131 such that air separation can be formed below the recess 23. In some embodiments, the recess 23 is formed on an upper surface of the re-distribution layer 20 in the process of forming the re-distribution layer 20, as shown in FIG. 2.

In some embodiments, as shown in FIG. 2, the base 10 includes a substrate 11 and a conductive layer 12 and a dielectric layer 13 that are sequentially formed on the substrate 11. The first opening 131 is formed in the dielectric layer 13, the re-distribution layer 20 is formed on the dielectric layer 13, and the re-distribution layer 20 is connected to the conductive layer 12. The first opening 131 is formed in the dielectric layer 13, and therefore in the process of forming the re-distribution layer 20 on the dielectric layer 13, the recess 23 can be formed in the re-distribution layer 20, thereby reducing the difficulty of fabricating a semiconductor structure and improving the efficiency of fabricating a semiconductor structure.

In some embodiments, a plurality of conductive layers 12 can be formed on the substrate 11, and the re-distribution layer 20 can be connected to one of the conductive layers 12. For example, one via hole is formed in the dielectric layer 13, and the via hole can expose one of the conductive layers 12. A metal material is deposited in the via hole to implement electrical connection between the re-distribution layer 20 and the conductive layer 12 in the process of forming the re-distribution layer 20.

In some embodiments, the first opening 131 exposes the conductive layer 12, i.e., the first opening 131 may be a via hole, thereby increasing a depth of the first opening 131, such that a reliable recess 23 can be formed in the re-distribution layer 20.

In some embodiments, the first opening 131 may not expose the conductive layer 12, i.e., a bottom wall of the first opening 131 may be within the dielectric layer 13, thereby shortening a time taken for forming the first opening 131.

In some embodiments, the substrate 11 may include a portion formed by a silicon-containing material. The substrate 11 can be formed by any suitable material, including, for example, at least one of silicon, monocrystalline silicon, polycrystalline silicon, amorphous silicon, silicon germanium, monocrystalline silicon germanium, polycrystalline silicon germanium, and carbon-doped silicon.

The dielectric layer 13 may be an insulation layer. For example, a material of the dielectric layer 13 may include, but is not limited to, one or more of insulating materials such as silicon oxide, silicon nitride, and ethyl orthosilicate (TEOS).

The conductive layer 12 is made of a conductive material, and the conductive layer 12 can be made of a metal material. For example, the conductive layer 12 can be made of an aluminum material, or the conductive layer 12 can be made of a copper material. The re-distribution layer 20 is made of a conductive material, and the re-distribution layer 20 can be made of a metal material. For example, the re-distribution layer 20 can be made of an aluminum material, or the re-distribution layer 20 can be made of a copper material.

In some embodiments, the conductive layer 12 can be made of an aluminum material, and the re-distribution layer 20 can be made of an aluminum material, thereby improving the connection capabilities of the conductive layer 12 and the re-distribution layer 20, to form a reliable electrical connection between the conductive layer 12 and the re-distribution layer 20.

In some embodiments, the method for fabricating a semiconductor structure further includes: forming an optical identification layer 30 on the re-distribution layer 20; and forming a second opening 31 in the optical identification layer 30 to expose the bond pad 21, the probe pad 22, and the recess 23. The optical identification layer 30 can protect the re-distribution layer 20. For example, reflectivity of the optical identification layer 30 is lower than that of the probe pad 22, and reflectivity of the recess 23 is also lower than that of the probe pad 22 such that the optical identification layer 30 and the recess 23 can be used as an optical identification pattern around the probe pad 22.

The optical identification layer 30 may be a photoresist layer, or the optical identification layer 30 may be a polymer layer, and a material of the polymer layer may include, but is not limited to, polyimide, polybenzoxazole, and the like. The optical identification layer 30 is processed using a photolithography process to form a second opening 31, which exposes the bond pad 21, the probe pad 22, and the recess 23.

In some embodiments, a plurality of second openings 31 can be formed in the optical identification layer 30, the plurality of second openings 31 may be spaced apart, and each second opening 31 can expose the bond pad 21, the probe pad 22, and the recess 23. For example, there may be three second openings 31, each of which can expose the corresponding bond pad 21, probe pad 22, and recess 23, as shown in FIG. 8.

At least one embodiment of the present invention further provides a semiconductor structure. Referring to FIG. 2 to FIG. 8, the semiconductor structure includes: a base 10; a re-distribution layer 20, where the re-distribution layer 20 is disposed on the base 10 and includes a bond pad 21 and a probe pad 22, the bond pad 21 and the probe pad 22 are disposed adjacent to each other, and a recess 23 is formed in the re-distribution layer 20 and is disposed between the bond pad 21 and the probe pad 22.

The semiconductor structure in some embodiments of the present invention includes a base 10 and a re-distribution layer 20, the re-distribution layer 20 is disposed on the base 10 and includes a bond pad 21 and a probe pad 22 that are disposed adjacent to each other, and a recess 23 is formed in the re-distribution layer 20 and is disposed between the bond pad 21 and the probe pad 22 such that the recess 23 can be used as an optical identification pattern on a side of the probe pad 22, thereby avoiding a problem that because there is no optical identification pattern between the bond pad 21 and the probe pad 22, a test device cannot identify the probe pad 22 during automatic testing, causing an error. As such, test performance of the semiconductor structure is improved.

It should be noted that when the test device (for example, the test device that includes a probe) is used to be used for electrical performance testing on the semiconductor structure, the test device is in contact with the probe pad 22. In such a process, an optical device is needed to identify a circumferential region of the probe pad 22. If there is no optical identification pattern between the bond pad 21 and the probe pad 22, for example, the bond pad 21 and the probe pad 22 are in direct communication, the optical device cannot accurately identify the location region of the probe pad 22 in such case, causing an error, thereby affecting the electrical performance testing on the semiconductor structure. In some embodiments, because the recess 23 is formed in the re-distribution layer 20 and is disposed between the bond pad 21 and the probe pad 22, the recess 23 can be used as an optical identification pattern between the bond pad 21 and the probe pad 22 such that the location region of the probe pad 22 can be accurately identified, thereby performing electrical performance testing on the semiconductor structure.

In some embodiments, the re-distribution layer 20 includes an optical identification layer 30, which protects the re-distribution layer 20, and the optical identification layer 30 needs to expose the bond pad 21, the probe pad 22, and the recess 23 such that the bond pad 21 can be configured to connect to an external device, and the probe pad 22 can be configured to be used for electrical performance testing on the semiconductor structure.

A recess 23 can be directly provided between the bond pad 21 and the probe pad 22, that is, both side edges of the opening of the recess 23 are connected to the bond pad 21 and the probe pad 22, respectively. In such case, the optical identification layer 30 and the recess 23 around the probe pad 22 can be used as an optical identification pattern around the probe pad 22.

In some embodiments, the base 10 includes a first opening 131, which faces toward the re-distribution layer 20. A first orthographic projection of the recess 23 on the base 10 is within a second orthographic projection of the first opening 131 on the base 10. The re-distribution layer 20 includes an optical identification layer 30, and the optical identification layer 30 includes a second opening 31 to expose the bond pad 21, the probe pad 22, and the recess 23.

The first opening 131 can be provided in the process of forming the re-distribution layer 20 and the recess 23 is formed in the re-distribution layer 20, and the second opening 31 exposes the bond pad 21, the probe pad 22, and the recess 23. As such, the bond pad 21 can be configured to connect to an external device, the probe pad 22 can be configured to be used for electrical performance testing on the semiconductor structure, and the recess 23 can be used as an optical identification pattern around the probe pad 22.

In some embodiments, the semiconductor structure includes one recess 23, and the bond pad 21 and the probe pad 22 are respectively disposed on two opposite sides of the recess 23 such that the recess 23 can be used as an optical identification pattern around the probe pad 22, such that the probe pad 22 can be used for electrical performance testing on the semiconductor structure.

The recess 23 includes a first edge and a second edge, the first edge and the second edge intersect the edges of the bond pad 21 and the probe pad 22, respectively, and the recess 23 can be used as an optical identification pattern adjacent to the probe pad 22 and together with the optical identification layer 30, surrounds the probe pad 22.

In some embodiments, as shown in FIG. 3, the widths of the recess 23 sampled along a length direction of the recess are uniform such that the structure is simple and the recess 23 is easily formed, thereby improving the efficiency of fabricating a semiconductor structure. In addition, the recess 23 having the uniform widths can be used as an optical identification pattern around the probe pad 22.

In some embodiments, the widths of the recess 23 is varied such that a pattern formed by the recess 23 can be more easily identified, thereby improving the efficiency of identifying the pattern.

In some embodiments, as shown in FIG. 4, the widths of the recess 23 sampled along the length direction of the recess gradually decreases from two opposite edge regions 231 to a middle region 232 such that a pattern formed by the recess 23 can be identified more easily, such that the recess 23 does not occupy an excessive area of the probe pad 22 and the bond pad 21, thereby improving the structural utility of the re-distribution layer 20.

As shown in FIG. 4, some opening widths of the middle region 232 of the recess 23 may be uniform, and the opening widths of the two outer portions of the recess 23 are in a variable-size structure. In some embodiments, it is possible that the recess 23 integrally includes two tapered portions.

In some embodiments, the semiconductor structure includes a plurality of recesses 23, and the bond pad 21 and the probe pad 22 are respectively disposed on two opposite sides of a recess region formed by the plurality of recesses 23 such that the plurality of recesses 23 can jointly be used as an optical identification pattern adjacent to the probe pad 22, such that that the probe pad 22 can be used for electrical performance testing on the semiconductor structure.

In some embodiments, the recesses 23 extend in a first direction and the plurality of recesses 23 are spaced apart in a second direction perpendicular to the first direction (e.g., the length direction of the opening region formed by the plurality of first openings 131). The first direction is substantially parallel to the edge line of the probe pad 22 in boundary with the recess region formed by the plurality of the recesses, i.e., there may be at least two separate recesses 23 between the probe pad 22 and the bond pad 21.

In some embodiments, the probe pad 22 and the bond pad 21 may be substantially rectangular in shape, and the opposite edge lines of the probe pad 22 and the bond pad 21 may be substantially in parallel. In such case, an extension direction of the opposite edge lines of the probe pad 22 and the bond pad 21 may be the first direction, and a direction perpendicular to the opposite edge lines of the probe pad 22 and the bond pad 21 may be the second direction. As shown in FIG. 5, there may be two spaced recesses 23 between the probe pad 22 and the bond pad 21, the recesses 23 extend in the first direction, and the two recesses 23 are spaced apart in the second direction.

The widths of the recesses 23 sampled in the first direction may be uniform, as shown in FIG. 5. In some embodiments, at least some of the widths of the recess 23 sampled in the first direction are varied. For example, the recesses 23 shown in FIG. 5 may be replaced with the recess 23 shown in FIG. 4. A specific structure of the recess 23 extending in the first direction is not limited herein.

In some embodiments, as shown in FIG. 6, the plurality of recesses 23 are spaced apart in the first direction, and the first direction is substantially parallel to the edge line of the probe pad 22 such that the plurality of independent recesses 23 jointly form an optical identification pattern of the probe pad 22.

In some embodiments, as shown in FIG. 7, the plurality of recesses 23 are arranged in at least two rows in the second direction perpendicular to the first direction such that the plurality of recesses 23 in an array jointly form an optical identification pattern of the probe pad 22.

It should be noted that a quantity and a specific structural form of the recesses 23 may not be limited, provided that the recess(es) 23 can be used as an optical identification pattern of the probe pad 22.

In some embodiments, the re-distribution layer 20 is made of a conductive material, and the re-distribution layer 20 can be made of a metal material. For example, the re-distribution layer 20 can be made of an aluminum material, or the re-distribution layer 20 can be made of a copper material. The material of the re-distribution layer 20 is not limited herein, and may be selected according to actual requirements.

In some embodiments, as shown in FIG. 2, the base 10 includes: a substrate 11, a conductive layer 12, and a dielectric layer 13. The conductive layer 12 is disposed on the substrate 11 and the re-distribution layer 20 is connected to the conductive layer 12. The dielectric layer 13 is disposed on the substrate 11 and includes a first opening 131. A first orthographic projection of the recess 23 on the substrate 11 is within a second orthographic projection of the first opening 131 on the substrate 11. The first opening 131 can be provided in the process of forming the re-distribution layer 20 and the recess 23 is formed in the re-distribution layer 20, thereby reducing the difficulty of fabricating a semiconductor structure and improving the efficiency of fabricating a semiconductor structure.

The first opening 131 in the dielectric layer 13 may be a hole section, which can have one open end facing toward the re-distribution layer 20 such that the recess 23 can be formed in the re-distribution layer 20 in the process of forming the re-distribution layer 20. The first opening 131 in the dielectric layer 13 may be a via hole, one open end of which faces toward the re-distribution layer 20 such that the recess 23 can be formed in the re-distribution layer 20 in the process of forming the re-distribution layer 20, and the other open end of the dielectric layer 13 may face toward the conductive layer 12.

The base 10 may include a plurality of conductive layers 12, and the re-distribution layer 20 can be connected to one conductive layer 12. For example, one via hole is formed in the dielectric layer 13, and the via hole can expose one conductive layer 12. A metal material is deposited in the via hole to implement electrical connection (not shown in the figure) between the re-distribution layer 20 and the conductive layer 12 in the process of forming the re-distribution layer 20.

In some embodiments, the conductive layer 12 is made of a conductive material, and the conductive layer 12 can be made of a metal material. For example, the conductive layer 12 can be made of an aluminum material, or the conductive layer 12 can be made of a copper material. The material of the conductive layer 12 is not limited herein, and may be selected according to actual requirements. The conductive layer 12 may be a metal wire.

In some embodiments, the conductive layer 12 can be made of an aluminum material, and the re-distribution layer 20 can be made of an aluminum material, thereby improving the connection of the conductive layer 12 and the re-distribution layer 20, to form a reliable electrical connection between the conductive layer 12 and the re-distribution layer 20.

In some embodiments, the substrate 11 may include a portion formed by a silicon-containing material. The substrate 11 can be formed by any suitable material, including, for example, at least one of silicon, monocrystalline silicon, polycrystalline silicon, amorphous silicon, silicon germanium, monocrystalline silicon germanium, polycrystalline silicon germanium, and carbon-doped silicon.

The dielectric layer 13 may be a polymer layer, for example, the dielectric layer 13 may include, but is not limited to, a polyimide layer or a polybenzoxazole layer. The dielectric layer 13 may be a layer of ethyl orthosilicate (TEOS).

In some embodiments, the re-distribution layer 20 fills a portion of the first opening 131, that is, in the process of forming the re-distribution layer 20, a portion of the re-distribution layer 20 sinks into the first opening 131 such that a recess 23 can be formed in the re-distribution layer 20.

It should be noted that a structural form of the first opening 131 may be substantially consistent with that of the recess 23. For example, when one recess 23 is present, there may be one first opening 131. In some embodiments, when a plurality of recesses 23 is present, there may be a plurality of first openings 131. Widths of the recesses 23 can be uniform, and in such case, widths of the first openings 131 may be uniform. Some widths of the recess 23 may be varied, and in such case, some widths of the first opening 131 may be varied. A structural form of the first opening 131 may be substantially consistent with that of the recess 23. However, this does not necessarily mean that the opening width of the recess 23 must be consistent with the opening width of the first opening 131.

In some embodiments, as shown in FIG. 2, an air gap 24 is formed on a side of the re-distribution layer 20 facing toward the first opening 131 such that air separation can be formed below the recess 23, and therefore the recess 23 can be formed on an upper surface of the re-distribution layer 20 in the process of forming the re-distribution layer 20.

In some embodiments, as shown in FIG. 2, the first opening 131 exposes the conductive layer 12, i.e., the first opening 131 may be a via hole, thereby increasing a depth of the first opening 131, such that a reliable recess 23 can be formed in the re-distribution layer 20.

In some embodiments, the first opening 131 may not expose the conductive layer 12, i.e., a bottom wall of the first opening 131 may be within the dielectric layer 13, thereby shortening a time taken for forming the first opening 131.

In some embodiments, the width of the first opening 131 is not greater than 3 μm, such that the recess 23 can be formed in the re-distribution layer 20, the following case can be avoided: In the process of forming the re-distribution layer 20, a large quantity of metal materials are deposited into the first opening 131, and consequently a large-size recess 23 is formed in the re-distribution layer 20, thereby affecting the structural performance of the re-distribution layer 20.

In some embodiments, the width of the first opening 131 is 1 μm to 3 μm, which not only can ensure that the recess 23 can be formed in the re-distribution layer 20, but also can avoid the recess 23 being too small such that the recess 23 can reliably be used as the optical identification pattern of the probe pad 22.

In some embodiments, the width of the first opening 131 may be 1 μm, 1.1 μm, 1.2 μm, 1.3 μm, 1.5 μm, 1.6 μm, 1.8 μm, 2 μm, 2.1 μm, 2.2 μm, 2.3 μm, 2.5 μm, 2.6 μm, 2.7 μm, 2.8 μm, 2.9 μm, or 3 μm.

In some embodiments, as shown in FIG. 2, the semiconductor structure further includes an optical identification layer 30. The optical identification layer 30 is disposed on the re-distribution layer 20 and includes a second opening 31 to expose the bond pad 21, the probe pad 22, and the recess 23. The optical identification layer 30 can protect the re-distribution layer 20, and the optical identification layer 30 and the recess 23 can be used as an optical identification pattern around the probe pad 22.

The optical identification layer 30 may be a photoresist layer, or the optical identification layer 30 may be a polymer layer, and the polymer layer may include, but is not limited to, a polyimide layer or a polybenzoxazole layer.

In some embodiments, one second opening 31 can expose the bond pad 21, the probe pad 22, and the recess 23.

In some embodiments, as shown in FIG. 8, there may be a plurality of bond pads 21, a plurality of probe pads 22, and a plurality of recesses 23. The optical identification layer 30 may include a plurality of second openings 31, each of which can expose the corresponding bond pad 21, probe pad 22, and recess 23.

In some embodiments, the semiconductor structure is formed using the method for fabricating a semiconductor structure described above.

After considering the specification and practicing the invention disclosed herein, a person skilled in the art easily figures out other implementation solutions of the present invention. The present invention is intended to cover any variations, functions, or adaptive changes of the present invention. These variations, functions, or adaptive changes comply with general principles of the present invention, and include common knowledge or a commonly used technical means in the technical field that is not disclosed in the present invention. This specification and some example embodiments are merely considered illustrative, and the actual scope and the spirit of the present invention are pointed out by the appended claims.

It should be understood that the present invention is not limited to the precise structures that have been described above and shown in the drawings, and various modifications and changes can be made without departing from the scope of the present invention. The scope of the present invention is defined only by the appended claims.

What is claimed is:

1. A semiconductor structure, comprising:
a base; and
a re-distribution layer, wherein the re-distribution layer is disposed on the base and comprises a bond pad and a probe pad, the bond pad and the probe pad are disposed adjacent to each other, and at least one recess is formed in the re-distribution layer and is disposed between the bond pad and the probe pad.

2. The semiconductor structure according to claim 1, wherein the at least one recess consists of one recess, and the bond pad and the probe pad are respectively disposed on two opposite sides of the recess.

3. The semiconductor structure according to claim 2, wherein widths of the recess sampled along a length direction of the recess are uniform.

4. The semiconductor structure according to claim 2, wherein widths of the recess sampled along a length direction of the recess are varied.

5. The semiconductor structure according to claim 4, wherein the widths of the recess gradually decrease from two opposite edge regions of the recess to a middle region of the recess.

6. The semiconductor structure according to claim 1, wherein the at least one recess consists of a plurality of the recesses, and the bond pad and the probe pad are respectively disposed on two opposite sides of a recess region formed by the plurality of the recesses.

7. The semiconductor structure according to claim 6, wherein the recesses are disposed and spaced apart along a width direction of the recess region.

8. The semiconductor structure according to claim 6, wherein the recesses are disposed and spaced apart along a length direction of the recess region, and the length direction of the recess region is substantially parallel to an edge line between the probe pad and the recesses.

9. The semiconductor structure according to claim 8, wherein the plurality of the recesses are arranged in at least two rows in the recess region.

10. The semiconductor structure according to claim 1, wherein the base comprises:
a substrate;
a conductive layer, wherein the conductive layer is disposed on the substrate, and the re-distribution layer is connected to the conductive layer; and
a dielectric layer, wherein the dielectric layer is disposed on the conductive layer and comprises a first opening, and a first orthographic projection of the recess on the substrate is within a second orthographic projection of the first opening on the substrate.

11. The semiconductor structure according to claim 10, wherein the re-distribution layer fills a portion of the first opening.

12. The semiconductor structure according to claim 11, wherein an air gap is formed on a side of the re-distribution layer facing toward the first opening.

13. The semiconductor structure according to claim 10, wherein the first opening exposes the conductive layer.

14. The semiconductor structure according to claim 10, wherein a width of the first opening is not greater than 3 μm.

15. The semiconductor structure according to claim 10, wherein a width of the first opening is 1 μm to 3 μm.

16. The semiconductor structure according to claim 10, wherein the semiconductor structure further comprises:
an optical identification layer, wherein the optical identification layer is disposed on the re-distribution layer, and
the optical identification layer comprises a second opening to expose the bond pad, the probe pad, and the recess.

17. A method for fabricating a semiconductor structure, comprising:
providing a base;
forming a first opening in the base; and
forming a re-distribution layer on the base such that a recess is formed between a bond pad and a probe pad of the re-distribution layer, wherein
a first orthographic projection of the recess on the base is within a second orthographic projection of the first opening on the base.

18. The method for fabricating a semiconductor structure according to claim 17, wherein
a plurality of first openings are formed in the base, so that a plurality of recesses are formed in the re-distribution layer.

19. The method for fabricating a semiconductor structure according to claim 17, wherein the base comprises a substrate and a conductive layer and a dielectric layer that are sequentially formed on the substrate, the first opening is formed in the dielectric layer, and the re-distribution layer is formed on the dielectric layer.

20. The method for fabricating a semiconductor structure according to claim 17, further comprising:
forming an optical identification layer on the re-distribution layer; and
forming a second opening in the optical identification layer to expose the bond pad, the probe pad, and the recess.
